(19) United States
(12) Patent Application Publication
(10) Pub. No.: US 2008/0055857 A1
(43) Pub. Date: Mar. 6, 2008

(54) Method for connecting heat pipes and a heat sink

(76) Inventors: Shyh-Ming Chen, Taipei Hsien (TW); Chiou-Tziy Chin, Taipei Hsien (TW)

Correspondence Address: SHYH-MING CHEN, 235 Chung - Ho, Box 8-24, Taipei, omitted

(21) Appl. No.: 11/515,188

(22) Filed: Sep. 5, 2006

(51) Int. Cl. H05K 7/20

(52) U.S. Cl. 361/703

(57) ABSTRACT

A method for connecting heat pipes and a heat sink comprises the steps of drilling a set of through holes through a heat dissipating base slab, implanting heat pipes through the through holes, integrating the heat-dissipating base slab with the heat pipes by punching using a press machine, and bending and twisting the heat pipes according to a predetermined angle and shape, whereby a set of radiation fins will be connected. The heat radiating device thereby produced is used on electronic elements.

### FIELD OF THE INVENTION

The present invention relates to methods for connecting heat pipes and heat sinks, more particularly to a method for connecting a plurality of heat pipes and a sink wherein the heat pipes and the heat sink are integrated by punching, assuring the tight connection between the two. Thereby, the efficiency of thermal conduction is enhanced.

### BACKGROUND OF THE INVENTION

Heat-dissipating devices for electronic elements of the prior art require high efficiency of thermal dissipation, which combine a heat sink, heat pipes and radiation fins. Thereby, the heat generated within an electronic element can be conducted away through a large contact surface with the sink. The heat sink is in direct contact with the element for fast thermal conduction, In other words, the degree of integration of the sink and the pipes directly affects the efficiency of heat dissipation of the thermal radiator. Therefore, to achieve a better tightness between the sink and the pipes can enhance heat radiation significantly.

Referring to FIG. 16, a thermal radiator of the prior art has a sink base 90 and a plurality of heat pipes 94. One side of the sink base 90 is provided with a groove 91 that can be covered by a cover plate 92 (also having a groove 93). The sink base 90 and the cover plate 92 are combined to form a through hole for housing the heat pipes 94. The cover plate 92 is retained on the sink base 90 by two projections 95 at two opposite ends of the sink base 90.

However, the above-mentioned prior devices will inevitably cause slits and gaps between the sink 90 and the pipes 94, therefore influencing the heat dissipation.

### SUMMARY OF THE INVENTION

Accordingly, the primary objective of the present invention is to provide a method for connecting a plurality of heat pipes and a heat sink comprising the steps of drilling a set of through holes through a heat dissipating base slab, implanting heat pipes through the through holes, integrating the heat-dissipating base slab with the heat pipes by punching using a press machine, and bending and twisting the heat pipes according to a predetermined angle and shape, whereby a set of radiation fins will be connected. The heat radiating device thereby produced is easy to made and of high efficiency of thermal conduction.

The various objects and advantages of the present invention will be more readily understood from the following detailed description when read in conjunction with the appended drawings.

### BRIEF DESCRIPTION OF THE DRAWINGS

FIG. 1 is an exploded perspective view of the first preferred embodiment of the present invention.

FIG. 2 is a perspective view of the first preferred embodiment of the present invention.

FIG. 3 is a side cross-sectional view of the first preferred embodiment of the present invention before the press-casting.

FIG. 4 is a side cross-sectional view of the first preferred embodiment of the present invention after the press-casting.

FIG. 5 is a perspective view of the first preferred embodiment of the present invention in the step of bending and twisting the heat pipes.

FIG. 6 is a perspective view of the first preferred embodiment of the present invention in the step of bending and twisting the heat pipes, wherein the pipes are bent in another configuration.

FIG. 7 is a side cross-sectional view of the second preferred embodiment of the present invention after the press-casting.

FIG. 8 is a side cross-sectional view of the third preferred embodiment of the present invention after the press-casting.

FIG. 9 is a side cross-sectional view of the fourth preferred embodiment of the present invention after the press-casting.

FIG. 10 is a side cross-sectional view of the fifth preferred embodiment of the present invention after the press-casting.

FIG. 11 is a perspective view of the sixth preferred embodiment of the present invention after the press-casting.

FIG. 12 is a side cross-sectional view of the sixth preferred embodiment of the present invention after the press-casting.

FIG. 13 is a perspective view of the sixth preferred embodiment of the present invention after the step of bending and twisting the heat pipes, wherein the pipe holes are arranged differently.

FIG. 14 is a perspective view of the seventh preferred embodiment of the present invention.

FIG. 15 is a perspective view of the seventh preferred embodiment of the present invention after the press-casting.

FIG. 16 illustrates the combined structure of a heat sink and heat pipes of the prior art.

### DETAILED DESCRIPTION OF THE PREFERRED EMBODIMENTS

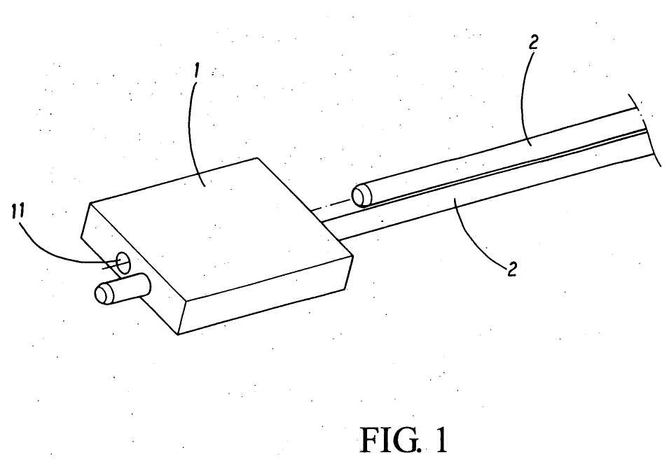

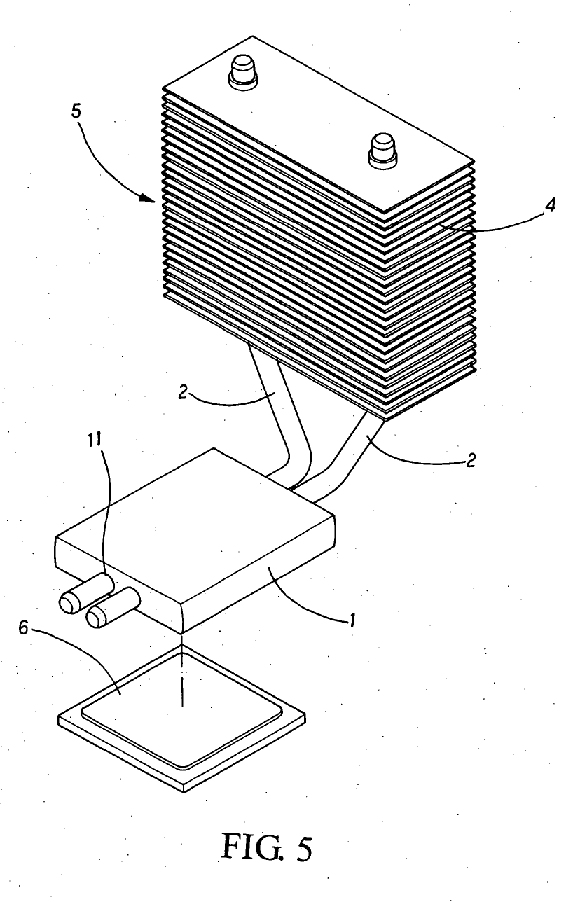

Referring to FIGS. 1 to 6, the first preferred embodiment of the present invention as a method for connecting a plurality of heat pipes and a heat sink comprises the steps of:

(1) drilling a set of through holes 11 through a heat dissipating base slab 1: The through holes 11 are located closer to one surface of the heat dissipating base slab 1, as shown in FIG. 1.

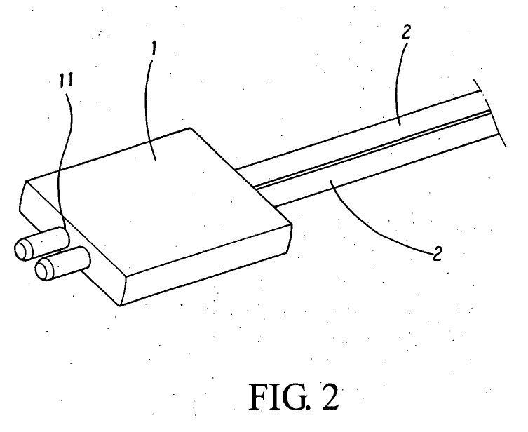

(2) implanting at least one heat pipe 2 through one of the through holes 11: As shown in FIG. 2, to what extent the heat pipe 2 goes through the heat dissipating base slab 1 depends on the design necessity.

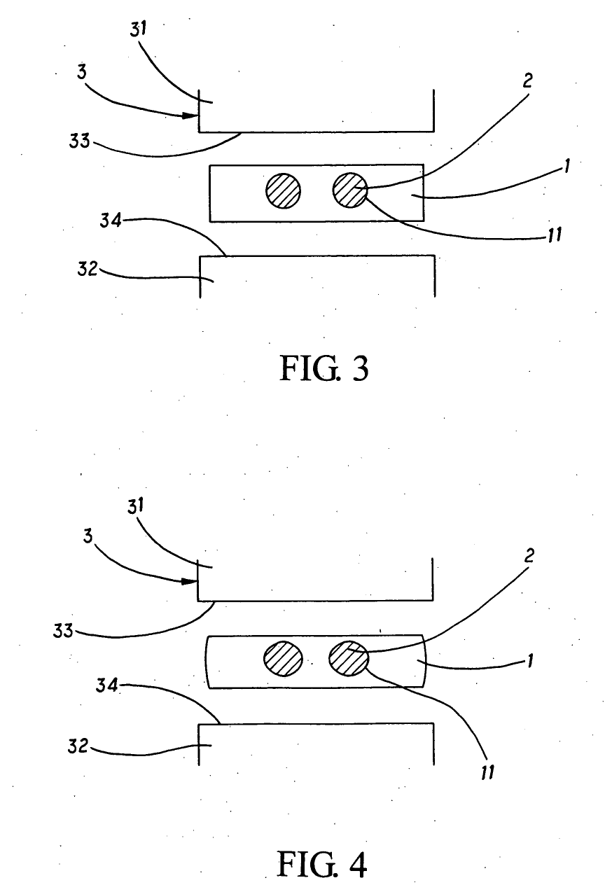

(3) applying a press machine 3 consisting of an upper part 31 and a lower casting part 32 perpendicular to the combination of the heat dissipating base slab 1 and the heat pipe(s) 2, as shown in FIG. 3. Each of the upper part 31 and the lower casting part 32 has a side facing the other that is provided with an impression portion (33, 34).

(4) press-shaping the heat-dissipating base slab 1 inserted with the heat pipe(s) 2 by the press machine 3 so that the upper part 31 and the lower casting part 32 thereof will clip the heat-dissipating base slab 1 and the heat pipe(s) 2, which are then integrated by mutual deformation. It is achieved by the punching of the impression portions (33, 34) so as to form a local deformed region to assist the integration.

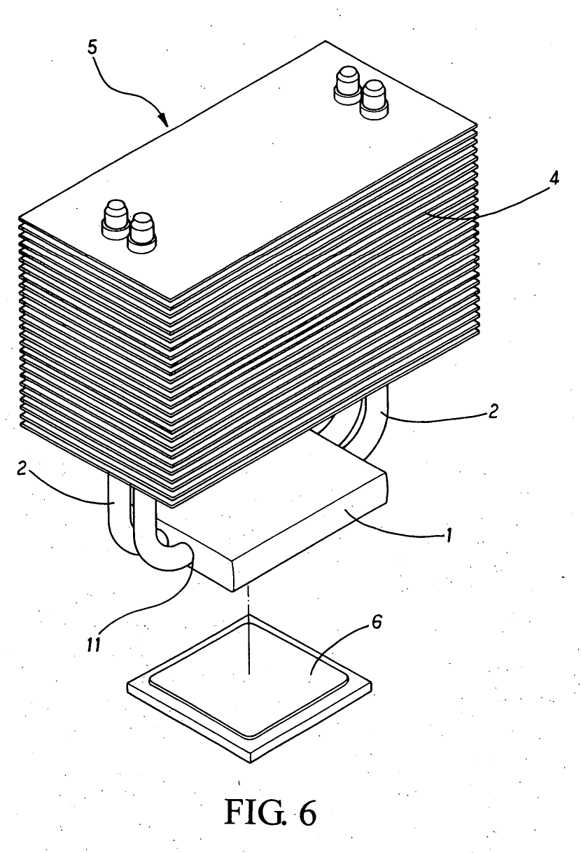

(5) bending and twisting the heat pipe(s) 2 according to a predetermined angle and shape, whereby a set of radiation fins 4 will be connected. The step achieves an extension of the heat pipe(s) 2 toward one side of the heat dissipating base slab 1 for connecting a plurality of heat radiation fins 4, as shown in FIG. 5. It can also be an extension of the heat pipe(s) 2 toward two opposite sides of the heat dissipating base slab 1, as shown in FIG. 6.

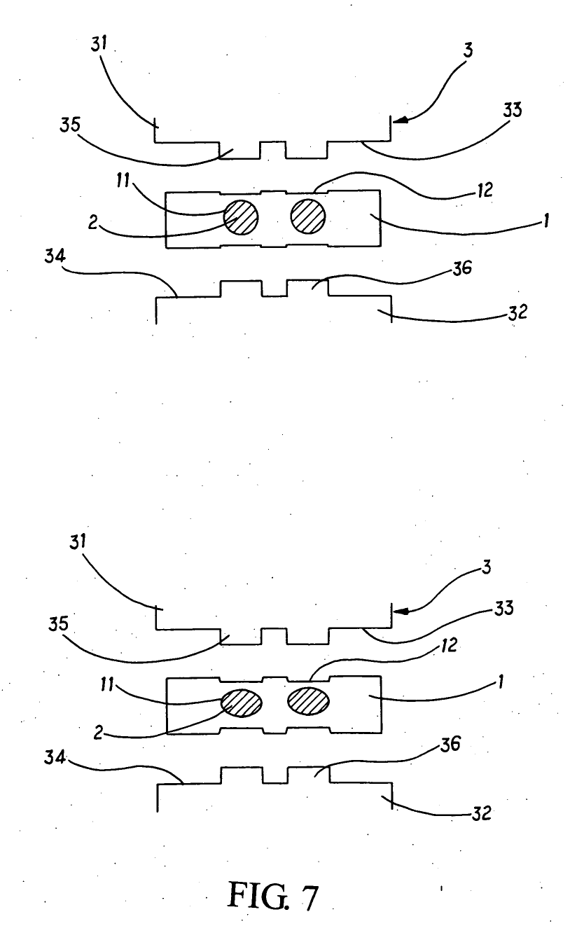

Referring to FIG. 7, the second preferred embodiment of the present invention as a method for connecting a plurality of heat pipes and a heat sink comprises the same steps 1-5 as those of the first preferred embodiment (as shown in FIGS. 1-5), except that one side of the heat dissipating base slab 1 is provided with a depressed portion 12, which is substantially a flat groove. The depressed portion 12 is located above the through holes 11 and can be engaged with the upper part 31 and the lower casting part 32 when the heat dissipating base slab 1 is punched by the impression portions 35, 36 of the press machine 3. Thereby, the heat dissipating base slab 1 and the heat pipes 2 will be integrated by local deformation through punching by the press machine 3.

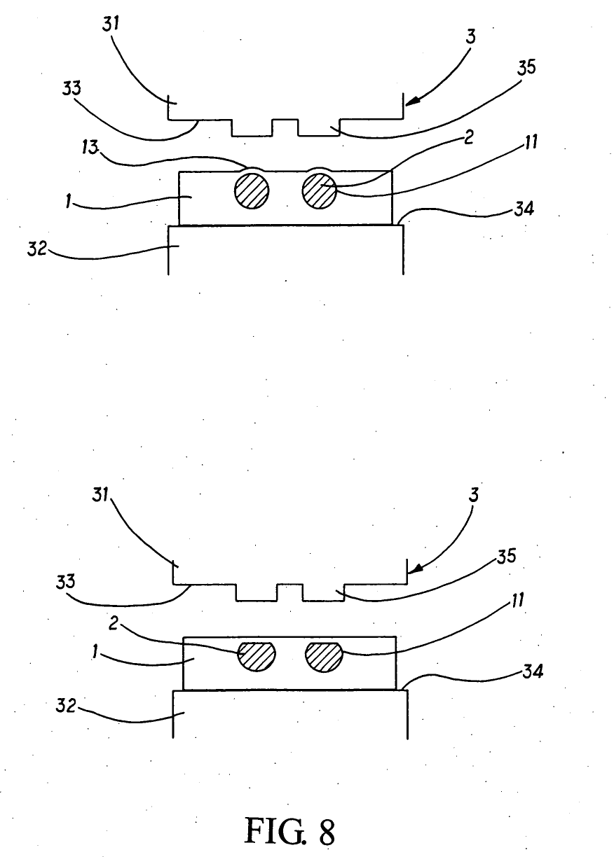

Referring to FIG. 8, the third preferred embodiment of the present invention as a method for connecting a plurality of heat pipes and a heat sink comprises the same steps 1-5 as those of the second preferred embodiment (as shown in FIG. 7), except that one side of the heat dissipating base slab 1 is provided with a bulged portion 13 located above the through holes 11 and can be engaged with one of the impression portions 35, 36 on the upper part 31 and the lower casting part 32 when by the press machine 3. Thereby, the heat dissipating base slab 1 and the heat pipes 2 will be integrated by local deformation through punching by the press machine 3.

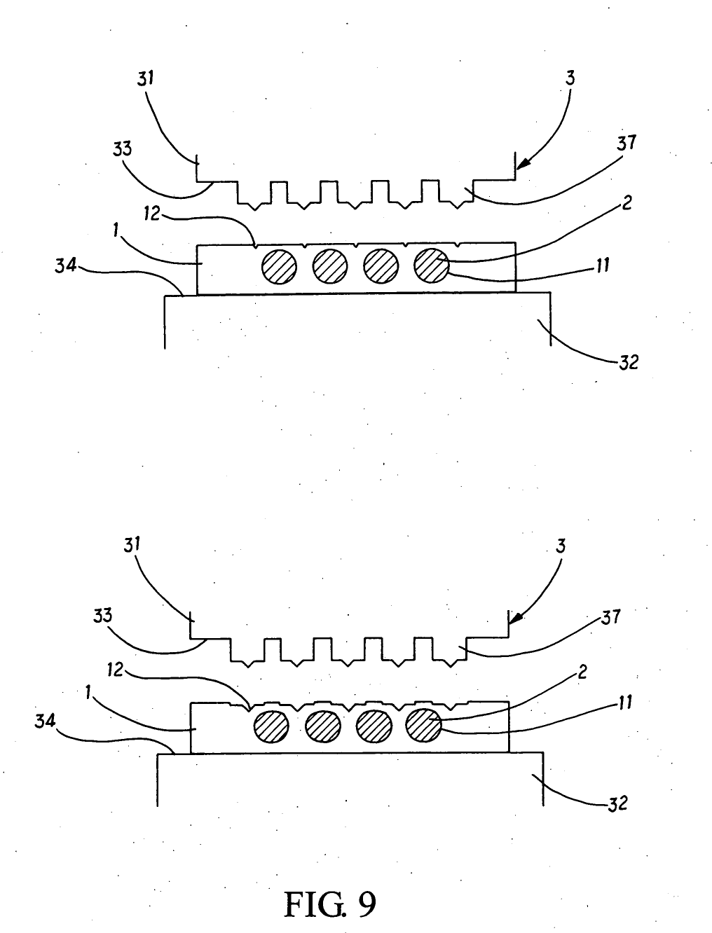

Referring to FIG. 9, the fourth preferred embodiment of the present invention as a method for connecting a plurality of heat pipes and a heat sink comprises the same steps 1-5 as those of the second and third preferred embodiments (as shown in FIGS. 7, 8), except that one side of the heat dissipating base slab 1 is provided with parallel depressed portions 12 with a V-shaped cross section located above the through holes 11 and that each of the upper part 31 and the lower casting part 32 of the press machine 3 is provided with corresponding impression portions 37 each with a V-shaped end to the V-shaped depressed portions 12. Thereby, the heat dissipating base slab 1 and the heat pipes 2 will be integrated by local deformation caused by the engagement between the impression portions 37 and the depressed portions 12 through press machine 3 punching.

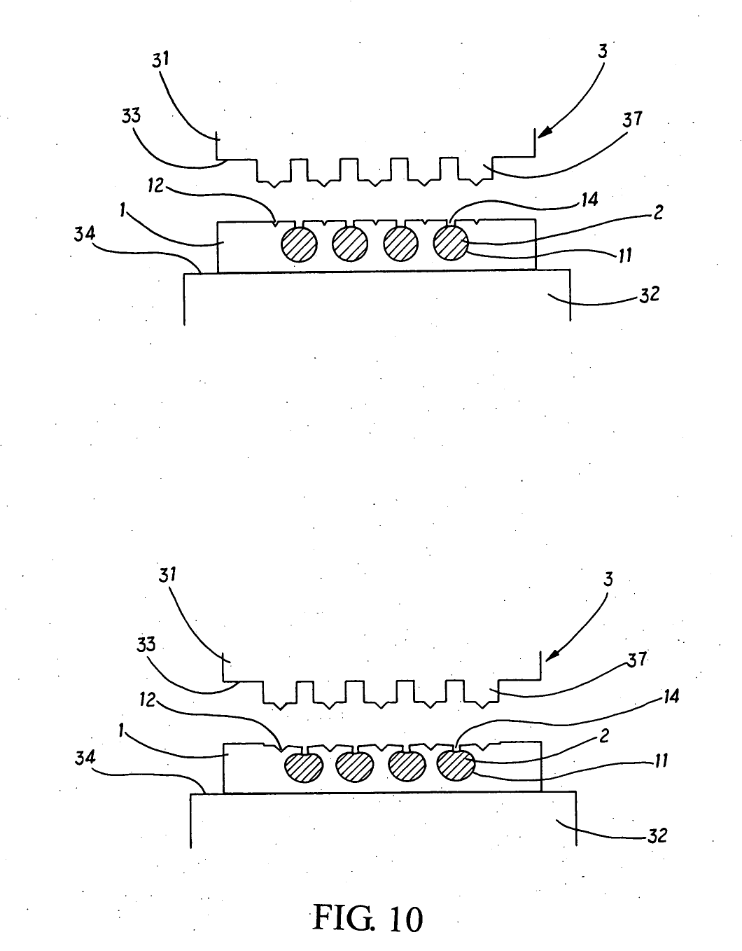

Referring to FIG. 10, the fifth preferred embodiment of the present invention as a method for connecting a plurality of heat pipes and a heat sink comprises the same steps as those of the fourth preferred embodiment (as shown in FIG. 9), except that the side of the heat dissipating base slab 1 with the V-shaped depressed portions 12 is further provided with transverse grooves 14 connecting adjacent depressed portions 12. Thereby, the heat dissipating base slab 1 and the heat pipes 2 will be integrated by local deformation caused by the engagement between the impression portions 37 and the depressed portions 12 through press machine 3 punching. At the same time, the spacing of the transverse grooves 14 will be changed, further enhancing the integration of the heat dissipating base slab 1 and the heat pipes 2.

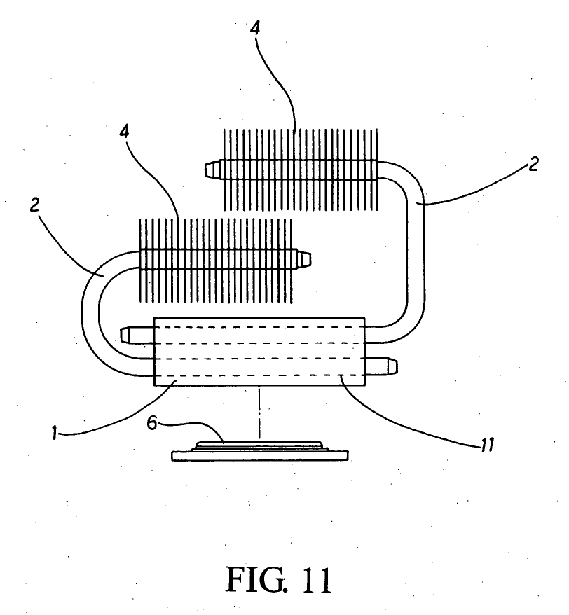

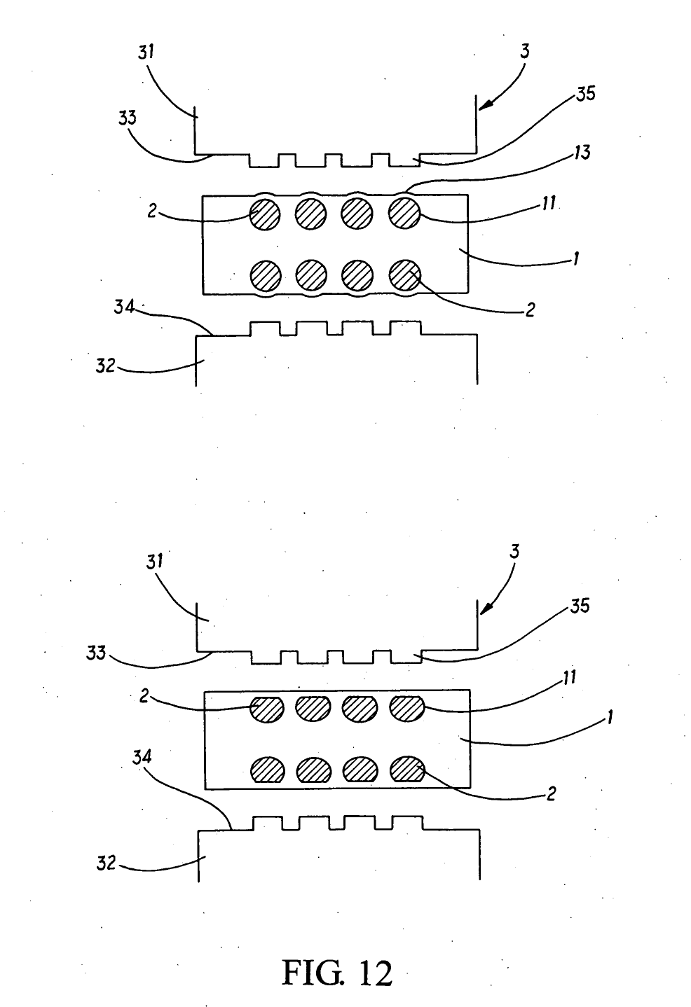

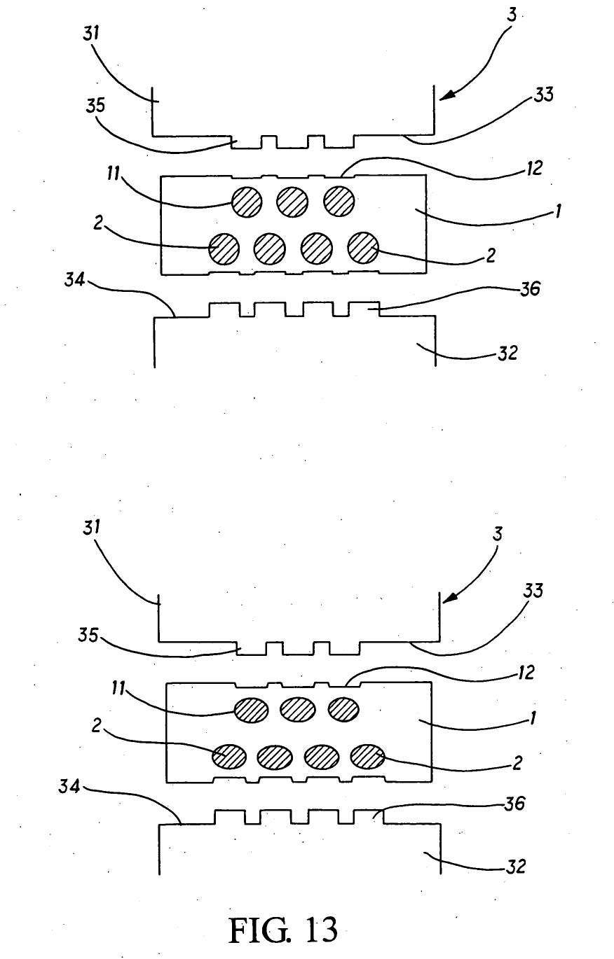

Referring to FIGS. 11-13, the sixth preferred embodiment of the present invention as a method for connecting a plurality of heat pipes and a heat sink comprises the same steps as the above-mentioned preferred embodiments, except either that upper and the lower rows of through holes are aligned so that each of the through holes in the upper row is located right above a corresponding one of the through holes in the lower row (as shown in FIG. 12), or that the upper and the lower rows of through holes are aligned so that each of the through holes in the upper row is located above the midpoint between two adjacent through holes in said lower row (as shown in FIG. 13). The heat pipes 2 are arranged within the heat dissipating base slab 1 as the arrangement of the through holes 11. Thereby, the heat dissipating base slab 1 and the heat pipes 2 will be integrated by local deformation caused by the depressed portions 12 or the bulged portions 13 through press machine 3 punching. The heat pipes 2 extended out of the heat dissipating base slab 1 are then bent and twisted according to a predetermined angle and shape, whereby a set of radiation fins 4 will be connected.

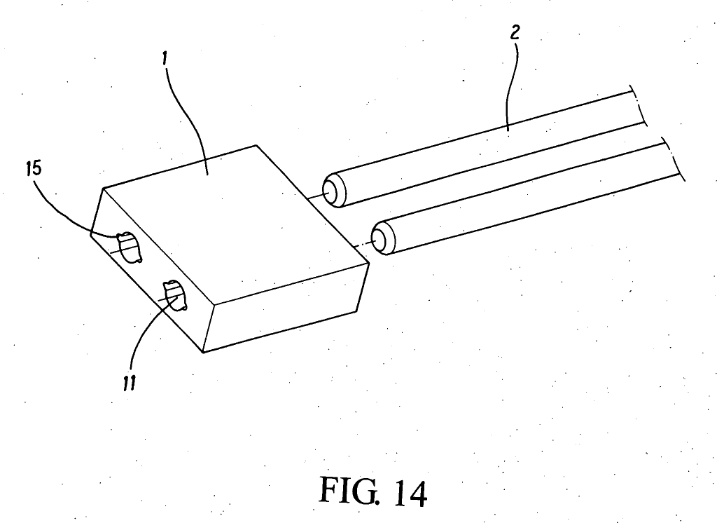

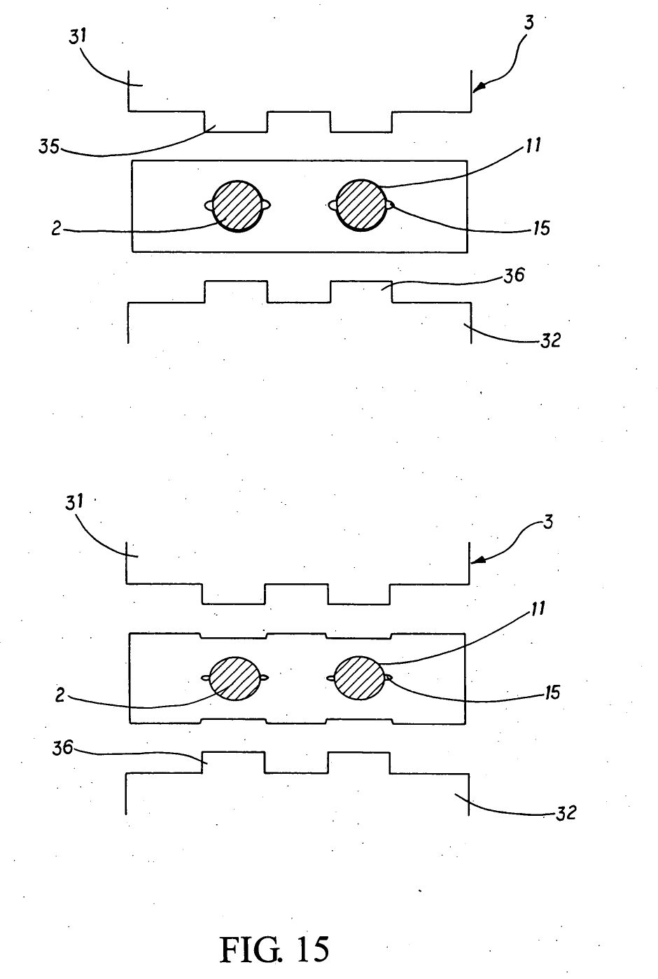

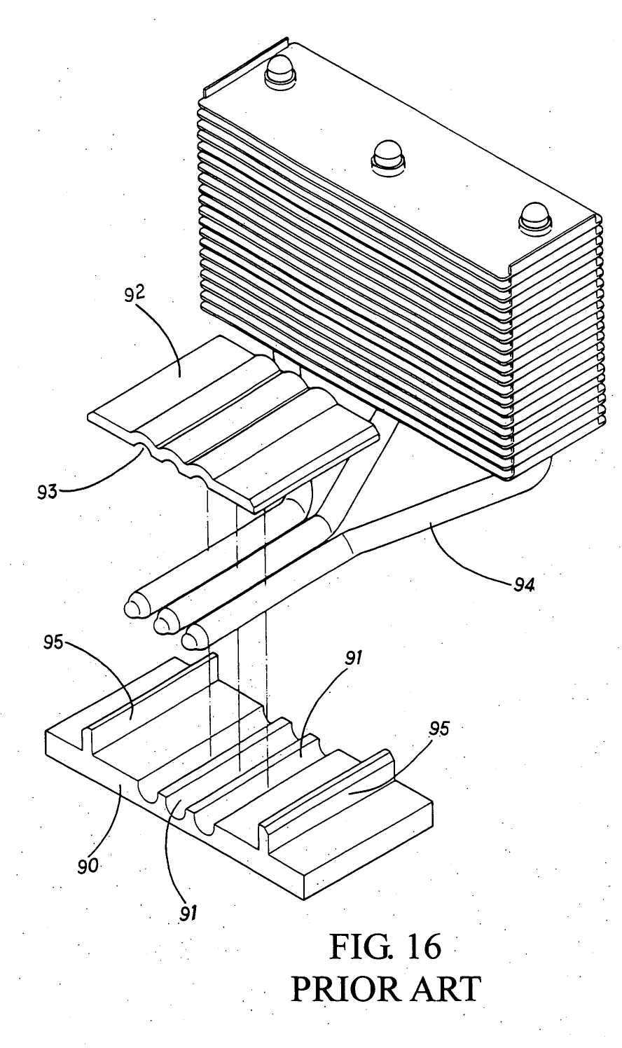

Referring to FIGS. 14, 15, the seventh preferred embodiment of the present invention as a method for connecting a plurality of heat pipes and a heat sink comprises the same steps as the above-mentioned preferred embodiments, except that each of the through holes 11 within the heat dissipating base slab 1 are further provided with parallel-run contraction passages 15, as shown in FIG. 15. The heat pipes 2 are arranged within the heat dissipating base slab 1 as the arrangement of the through holes 11. Thereby, the heat dissipating base slab 1 and the heat pipes 2 will be integrated by local deformation caused by the depressed portions 12 or the bulged portions 13 through press machine 3 punching.

In summary, the present invention may include the following methods.

(A) A first method for connecting a plurality of heat pipes and a heat sink, comprises the steps of: (1) drilling a set of through holes through a heat dissipating base slab; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected. The step further includes a step of applying a press machine in said step of press-shaping perpendicular to said combination of said heat dissipating base slab and said heat pipes so as to form a local deformed region to assist said integration of said heat dissipating base slab and said heat pipes. In the step, said press machine consists of an upper and lower casting parts each having a side facing the other casting part provided with an impression portion; said upper and lower casting parts pressing said heat dissipating base slab and said heat pipes to form an integral body. In the method, said step of bending and twisting is an extension of said heat pipes toward one side of said heat dissipating base slab for connecting a plurality of heat radiation fins. In the method said step of bending and twisting is an extension of said heat pipes by two opposite sides of said heat dissipating base slab for connecting a set of heat radiation fins.

(B) A second method for connecting a plurality of heat pipes and a heat sink, comprises the steps of: (1) drilling a set of through holes through a heat dissipating base slab and forming at least a depressed portion on at least one side of said heat dissipating base slab; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected. The method further comprises the step of utilizing a press machine consisting of an upper and lower casting parts each having a side facing the other casting part, said oppositely facing sides each being provided with an impression portion corresponding to said depressed portions; said upper and lower casting parts pressing said heat dissipating base slab and said heat pipes to form an integral body. The depressed portion is a straight groove.

(C) A third method for connecting a plurality of heat pipes and a heat sink, comprises the steps of: (1) drilling a set of through holes through a heat dissipating base slab and forming at least a bulged portion on at least one side of said heat dissipating base slab; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected. The method comprises the step of utilizing a press machine consisting of an upper and lower casting parts each having a side facing the other casting part, said oppositely facing sides each being provided with an impression portion corresponding to said bulged portions; said upper and lower casting parts pressing said heat dissipating base slab and said heat pipes to form an integral body.

(D) A fourth method for connecting a plurality of heat pipes and a heat sink, comprises the steps of: (1) drilling a set of through holes through a heat dissipating base slab and forming at least a V-shaped groove on at least one side of said heat dissipating base slab; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected. The method further comprises the step of utilizing a press machine consisting of an upper and lower casting parts each having a side facing the other casting part, said oppositely facing sides each being provided with an impression portion corresponding to said V-shaped grooves; said upper and lower casting parts pressing said heat dissipating base slab and said heat pipes to form an integral body.

(E) A fifth method for connecting a plurality of heat pipes and a heat sink, comprises the steps of: (1) drilling a set of through holes through a heat dissipating base slab and forming at least a V-shaped groove on at least one side of said heat dissipating base slab, said heat dissipating base slab further including a passage connecting said through holes; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected.

(F) A sixth method for connecting a plurality of heat pipes and a heat sink, comprises the steps of: (1) drilling an upper and a lower rows of through holes through a heat dissipating base slab; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected. The upper and said lower rows of through holes are aligned so that each of said through holes of said upper row is located right above one of said through holes of said lower row. The upper and said lower rows of through holes are aligned so that each of said through holes of said upper row is located above the mid point between two adjacent through holes of said lower row. The heat dissipating base slab further has at least one surface provided with at least a surface portion selected from a depressed portion, a bulged portion and a mixture of a bulged portion and an internal passage. The depressed portions on said heat dissipating base slab takes a cross section selected from a flat groove and a V-shaped groove.

(G) A seventh method for connecting a plurality of heat pipes and a heat sink, comprises the steps of: (1) drilling a set of through holes through a heat dissipating base slab, each of said through holes having lateral passages for contraction; (2) implanting at least one heat pipe through one of said through holes; (3) press-shaping said heat-dissipating base slab inserted with said heat pipe so that said heat-dissipating base slab and said heat pipe are integrated by mutual deformation; (4) bending and twisting said heat pipe according to a predetermined angle and shape, whereby a set of radiation fins will be connected.

The present invention is thus described, and it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for connecting a plurality of heat pipes and a heat sink, comprising the steps of:
(1) drilling a set of through holes through a heat dissipating base slab;
(2) implanting at least one heat pipe through one of said through holes;
(3) press-shaping said heat-dissipating base slab inserted with said heat pipe so that said heat-dissipating base slab and said heat pipe are integrated by mutual deformation;
(4) bending and twisting said heat pipe according to a predetermined angle and shape, whereby a set of radiation fins will be connected.

2. The method for connecting a plurality of heat pipes and a heat sink of claim 1 further including a step of applying a press machine in said step of press-shaping perpendicular to said combination of said heat dissipating base slab and said heat pipes so as to form a local deformed region to assist said integration of said heat dissipating base slab and said heat pipes.

3. The method for connecting a plurality of heat pipes and a heat sink of claim 2 wherein said press machine consists of an upper and lower casting parts each having a side facing the other casting part provided with an impression portion; said upper and lower casting parts pressing said heat dissipating base slab and said heat pipes to form an integral body.

4. The method for connecting a plurality of heat pipes and a heat sink of claim 1 wherein said step of bending and twisting is an extension of said heat pipes toward one side of said heat dissipating base slab for connecting a plurality of heat radiation fins.

5. The method for connecting a plurality of heat pipes and a heat sink of claim 1 wherein said step of bending and twisting is an extension of said heat pipes by two opposite sides of said heat dissipating base slab for connecting a set of heat radiation fins.

6. A method for connecting a plurality of heat pipes and a heat sink, comprising the steps of:
(1) drilling a set of through holes through a heat dissipating base slab and forming at least a depressed portion on at least one side of said heat dissipating base slab;
(2) implanting at least one heat pipe through one of said through holes;
(3) press-shaping said heat-dissipating base slab inserted with said heat pipe so that said heat-dissipating base slab and said heat pipe are integrated by mutual deformation;
(4) bending and twisting said heat pipe according to a predetermined angle and shape, whereby a set of radiation fins will be connected.

7. The method for connecting a plurality of heat pipes and a heat sink of claim 6 further comprising the step of utilizing a press machine consisting of an upper and lower casting parts each having a side facing the other casting part, said oppositely facing sides each being provided with an impression portion corresponding to said depressed portions; said upper and lower casting parts pressing said heat dissipating base slab and said heat pipes to form an integral body.

8. The method for connecting a plurality of heat pipes and a heat sink of claim 6 wherein said depressed portion is a straight groove.

9. A method for connecting a plurality of heat pipes and a heat sink, comprising the steps of:
(1) drilling an upper and a lower rows of through holes through a heat dissipating base slab;
(2) implanting at least one heat pipe through one of said through holes;
(3) press-shaping said heat-dissipating base slab inserted with said heat pipe so that said heat-dissipating base slab and said heat pipe are integrated by mutual deformation;
(4) bending and twisting said heat pipe according to a predetermined angle and shape, whereby a set of radiation fins will be connected.

10. The method for connecting a plurality of heat pipes and a heat sink of claim 9 wherein said upper and said lower rows of through holes are aligned so that each of said through holes of said upper row is located right above one of said through holes of said lower row.

11. The method for connecting a plurality of heat pipes and a heat sink of claim 9 wherein said upper and said lower rows of through holes are aligned so that each of said through holes of said upper row is located above the mid point between two adjacent through holes of said lower row.

12. The method for connecting a plurality of heat pipes and a heat sink of claim 9 wherein said heat dissipating base slab further has at least one surface provided with at least a surface portion selected from a depressed portion, a bulged portion and a mixture of a bulged portion and an internal passage.

13. The method for connecting a plurality of heat pipes and a heat sink of claim 12 wherein said depressed portions on said heat dissipating base slab takes a cross section selected from a flat groove and a V-shaped groove.
